(19) United States
(12) Patent Application Publication
(10) Pub. No.: US 2025/0163576 A1
(43) Pub. Date: May 22, 2025

(54) SUBSTRATE PROCESSING APPARATUS

(71) Applicant: EUGENE TECHNOLOGY CO., LTD., Yongin-si (KR)

(72) Inventors: In Soo SON, Hwaseong-si (KR); Chang Hun SHIN, Icheon-si (KR); Chan Yong PARK, Icheon-si (KR); Deog Hwan KIM, Yongin-si (KR); Jae Jun JUNG, Seoul (KR); Si Won RYU, Yongin-si (KR); Chang Min PARK, Seoul (KR); In Seong HWANG, Yongin-si (KR); Jae Sun KIM, Seoul (KR); Ki Hoon KIM, Suwon-si (KR); Jong Hoon KIM, Hwaseong-si (KR); Jeong Hyeon KIM, Yongin-si (KR)

(21) Appl. No.: 18/954,498

(22) Filed: Nov. 20, 2024

(30) Foreign Application Priority Data
Nov. 22, 2023 (KR) 10-2023-0163617

(51) Int. Cl. C23C 16/455; C23C 16/458

(52) U.S. Cl. CPC C23C 16/45544; C23C 16/45565; C23C 16/458

(57) ABSTRACT

The present disclosure relates to a substrate processing apparatus that controls supply of a process gas through a valve block. The substrate processing apparatus includes a substrate support on which a substrate is supported, a shower head part provided to face the substrate support and configured to inject a process gas toward the substrate, and a gas supply part configured to supply the process gas to the shower head part. The gas supply part includes a valve block part installed on an upper portion of the shower head part to adjust a flow of the process gas.

### CROSS-REFERENCE TO RELATED APPLICATION

This application claims priority to Korean Patent Application No. 10-2023-0163617 filed on Nov. 22, 2023 and all the benefits accruing therefrom under 35 U.S.C. § 119, the contents of which are incorporated by reference in their entirety.

### BACKGROUND

The present disclosure relates to a substrate processing apparatus, and more particularly, to a substrate processing apparatus that controls supply of a process gas through a valve block.

A substrate processing apparatus is an apparatus that deposits reactive particles contained in a process gas onto a substrate using a chemical vapor deposition (CVD) method or an atomic layer deposition (ALD) method after disposing the substrate into a process space. The substrate processing apparatus is classified into a single wafer type that may perform a processing process on one substrate and a batch type that may perform a processing process on a plurality of substrates.

In a semiconductor manufacturing process, the atomic layer deposition (ALD) process is performed by instantaneously supplying and discharging a large amount of gas at a pressure above a certain pressure to improve a unit per hour (UPH) production rate. However, there are limitations in minimizing a time due to delays caused by a distance between chambers after a final valve depending on a position of a valve installed in a gas line supplied to the chamber.

Thus, a substrate processing apparatus that is capable of improving productivity by shortening a gas supply time is required.

### PRIOR ART DOCUMENT

### [Patent Document]

Korean Patent No. 10-2028202

### SUMMARY

The present disclosure provides a substrate processing apparatus that controls supply of a process gas by installing a valve block part on an upper portion of a shower head part.

In accordance with an exemplary embodiment, a substrate processing apparatus includes: a substrate support on which a substrate is supported; a shower head part provided to face the substrate support and configured to inject a process gas toward the substrate; and a gas supply part configured to supply the process gas to the shower head part, wherein the gas supply part includes a valve block part installed on an upper portion of the shower head part to adjust a flow of the process gas.

The process gas may include a plurality of gases, and the gas supply part may be configured to sequentially supply the plurality of gases to the shower head part.

The valve block part may include: a plurality of valves to which a plurality of gas lines, through which the plurality of gases are supplied, are connected, respectively; and a valve block fixed to a top surface of the shower head part to support the plurality of valves.

The valve block part may further include a heater configured to heat the valve block.

The valve block part may further include a temperature measuring member configured to measure a temperature of the valve block.

The valve block may include an internal gas passage connected to each of the plurality of gas lines, and the valve may be configured to control a flow of each of the plurality of gases in the internal gas passage.

An inner surface of the internal gas passage may be surface-treated.

The valve block part may further include a plurality of gaskets, each of which is provided between each of the plurality of valves and the valve block.

The valve block part may be directly connected to an inlet of the shower head part.

The plurality of gases may include a source gas and a reactant gas, and the source gas and the reactant gas may be separated to be introduced into the inlet of the shower head part.

The substrate processing apparatus may further include a plurality of sub-chambers, each of which is provided with the substrate support and the shower head part and in which processes are performed independently, and the gas supply part may include: a gas hub to which the process gas is supplied; and a branch line part constituted by the gas lines branched from the gas hub and connected respectively to the shower head part of each of the plurality of sub-chambers.

The gas hub may be provided in plurality and each of the plurality of gases may be supplied to each of the gas hubs, and the branch line part may be provided in each of the gas hubs.

The plurality of valves may be connected respectively to the gas lines that are connected to the shower head part of the same sub-chamber by extending in the same direction from the different gas hubs.

The valve block part may be configured as an integrated type.

### BRIEF DESCRIPTION OF THE DRAWINGS

Exemplary embodiments can be understood in more detail from the following description taken in conjunction with the accompanying drawings, in which:

FIG. 1 is a schematic cross-sectional view of a substrate processing apparatus according to an exemplary embodiment;

FIG. 2 is a schematic perspective view of a valve block part according to an exemplary embodiment; and

FIG. 3 is a conceptual view for explaining a gas supply part that supplies a process gas to a plurality of sub-chambers according to an exemplary embodiment.

### DETAILED DESCRIPTION OF EMBODIMENTS

Hereinafter, specific embodiments will be described in more detail with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. In the descriptions, the same elements are denoted with the same reference numerals. In the figures, the dimensions of layers and regions are exaggerated for clarity of illustration. Like reference numerals refer to like elements throughout.

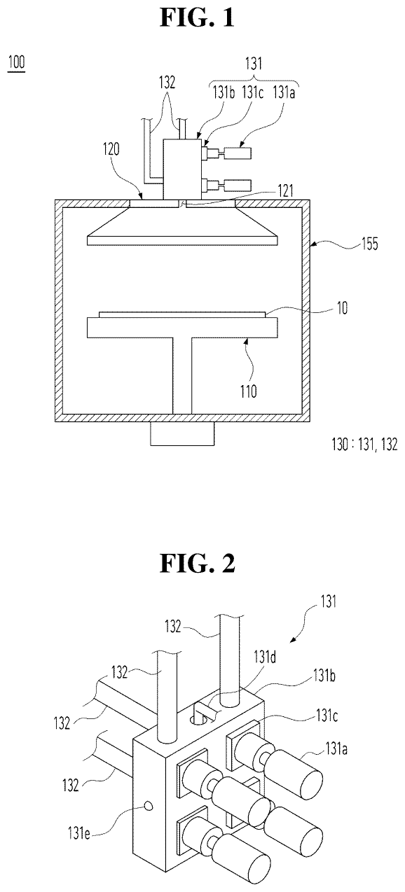

FIG. 1 is a schematic cross-sectional view of a substrate processing apparatus according to an exemplary embodiment.

Referring to FIG. 1, a substrate processing apparatus 100 according to an embodiment of the present disclosure may include a substrate support 110 on which a substrate 10 is supported, a shower head part 120 provided to face the substrate support 110 and injecting a process gas toward the substrate 10, and a gas supply part 130 supplying the process gas to the shower head part 120.

The substrate support 110 may support the substrate 10 to be processed, and substrate processing such as deposition may be performed by injecting the process gas onto the substrate 10 supported by the substrate support 110.

The shower head part 120 may be provided facing the substrate support 110 to supply the process gas toward the substrate 10 and inject the process gas for the substrate processing onto the substrate 10.

The gas supply part 130 may supply the process gas to the shower head part 120, may supply the process gas from a gas supply source (not shown), and may supply the process gas to the shower head part 120 through a gas line 132.

Here, the gas supply part 130 may be installed on an upper portion of the shower head part 120 and may include a valve block part 131 that controls a flow of the process gas. The valve block part 131 may be installed on the upper portion of the shower head part 120 and may regulate (or control) the flow (or supply) of the process gas supplied to the shower head part 120 through the gas line 132.

In the substrate processing apparatus 100 according to the present disclosure, the valve block part 131 may be installed on the upper portion of the shower head part 120 so that a position of the valve 131a that controls the supply of the process gas may be as close as possible to the inlet 121 of the shower head part 120, thereby shortening a supply time of the process gas, enabling a stable supply of the process gas, and improving substrate processing efficiency (or productivity).

Here, the process gas may include a plurality of gases, and the gas supply part 130 may sequentially supply the plurality of gases to the shower head part 120. The process gas may include a plurality of gases, a thin film or the like may be deposited on the substrate 10 through reaction of two or more gases, and the plurality of gases may include a purge gas in addition to a (direct) processing gas (e.g., a deposition gas or an etching gas).

In addition, the gas supply part 130 may sequentially supply the plurality of gases to the shower head part 120 and deposit reaction particles contained in the process gas (or each of the plurality of gases) on the substrate 10 using an atomic layer deposition (ALD) method. In the case of the atomic layer deposition (ALD), each reaction particles may be stacked (or deposited) in atomic layer units while alternately supplying the plurality of gases, and each of the alternately supplied gases may be supplied instantaneously for a short time to be stacked in atomic layer units.

In the related art, a valve may be installed in the middle of a gas line 132 between the gas supply source (not shown) and the shower head part 120 to cause a delay time due to a distance between the valve and the shower head part 120, and thus, an overall substrate processing time may inevitably increase. In addition, even if the valve is closed, the (process) gas may remain in the gas line 132 between the valve and the shower head part 120 and be continuously supplied to the shower head part 120, making it difficult to control a (one-time) deposition thickness of each reaction particle in atomic layer units, and since each of the plurality of gases is not supplied completely separated (e.g., separated temporally and/or spatially), two or more of the gases may react in air or within the shower head part 120 before reaching the substrate 10.

However, in the substrate processing apparatus 100 according to the present disclosure, the valve block part 131 may be installed on the upper portion of the shower head part 120 to immediately supply and stop (or block) each gas according to a supply control of the process gas through the valve 131a, thereby easily controlling the (one-time) deposition thickness of each reaction particle and completely supplying and separating each of the plurality of gases. That is, it is possible to prevent and/or suppress the two or more of the gases from reacting in the air or within the shower head part 120 before reaching the substrate 10.

FIG. 2 is a schematic perspective view of the valve block part according to an exemplary embodiment.

Referring to FIG. 2, the valve block part 131 may include a plurality of valves 131a to which a plurality of gas lines 132, through which the plurality of gases are respectively supplied, are respectively connected, and a valve block 131b fixed to a top surface of the shower head part 120 to support the plurality of valves 131a. The plurality of valves 131a may be respectively connected (or linked) to the plurality of gas lines 132 through which the plurality of gases are respectively supplied and may supply and block (or stop) the plurality of gases by opening and closing each of the plurality of gas lines 132.

The valve block 131b may be fixed to the top surface of the shower head part 120 and may support the plurality of valves 131a, and the valve block 131b may be fixed to the top surface of the shower head part 120 that is close to an inlet 121 of the shower head part 120 so that the plurality of valves 131a are provided (as close as possible) to the inlet 121 of the shower head part 120 through the valve block 131b. Thus, the supply and stop of each of the gases may be performed immediately according to a supply control of the process gas through the valve 131a, and it may be easy to control the (one-time) deposition thickness of each of the reaction particles, and also, each of the plurality of gases may be completely separated and supplied to prevent the two or more of the gases from reacting in the air or in the shower head part 120 before reaching the substrate 10.

Thus, in the substrate processing apparatus 100 according to the present disclosure, since a distance between each of the plurality of valves 131a and the shower head part 120 is minimized, there may be no limitation in supplying the process gas instantaneously, and since the gas is supplied at a rate of 0.2 ms or less, an atomic layer deposition (ALD) process may be stably performed without a time delay due to a length of the gas line 132.

In addition, the valve block part 131 may further include a heater 131d that heats the valve block 131b. The heater 131d may heat the valve block 131b, maintain (or heat) a temperature of the process gas transferred (or supplied) at a predetermined temperature (or constant temperature), and prevent a drop in temperature of the process gas and generation of particles during the process due to the decreases of the temperature. That is, the heater 131d may heat the valve block 131b to remove a cold spot when supplying the process gas, thereby preventing the temperature of the process gas from dropping (or becoming lower) (than the predetermined temperature), and preventing the particles, etc., from being generated during the process due to the drop in the temperature of the process gas. The heater 131d may be attached to and detached from the valve block 131b and replaced by being coupled to and separated from the valve block 131b.

Here, the valve block part 131 may further include a temperature measuring member 131e that measures the temperature of the valve block 131b. The temperature measuring member 131e may measure the temperature of the valve block 131b and may control the temperature of the valve block 131b by measuring the temperature of the valve block 131b. Here, the temperature measuring member 131e may include a temperature sensor such as a thermocouple TC.

For example, the substrate processing apparatus 100 of the present disclosure may further include a controller (not shown) that controls the heater 131d to control the temperature of the valve block 131b, and the temperature of the valve block 131b may be controlled through the controller (not shown) to control the temperature of the process gas to a target temperature (or a required temperature). Here, the controller (not shown) may read the temperature of the valve block 131b through the temperature measuring member 131e and control an output (e.g., output energy or energy emission intensity) of the heater 131d so that the valve block 131b reaches the control temperature (or target temperature) for controlling the temperature of the process gas to the target temperature. Here, the temperature of the valve block 131b may be read using the thermocouple installed at the outside of the valve block 131b, and a control thermocouple and a monitor thermocouple may also be installed. The control thermocouple may be used to control the temperature of the valve block 131b, and the monitor thermocouple may be used to detect an abnormal temperature to operate an automatic locking device such as an interlock.

That is, the substrate processing apparatus 100 according to the present disclosure may implement stability by mounting (or installing) the temperature measuring member 131e such as the thermocouple TC to eliminate risk factors occurring when the valve block 131b is heated.

In addition, the valve block 131b may include an internal gas passage connected to the plurality of gas lines 132, and the valve 131a may control a flow of each of the plurality of gases in the internal gas passage. The internal gas passage may be provided inside the valve block 131b, and each of the plurality of gases may flow, and also, the plurality of gases may flow to be spatially separated, or the plurality of gases may flow to be temporally separated.

In addition, the valve 131a may control the flow of the plurality of gases in the internal gas passage, and the plurality of valves 131a may open and close each of the plurality of gas lines 132 by blocking and releasing (or opening) the internal gas passage to supply and block each of the plurality of gases.

For example, the internal gas passage may be provided in plurality (or two or more), and the number of internal gas passage may be the same as the number of gas lines 132. The internal gas passages may be respectively connected to the plurality of gas lines 132, and each of the plurality of gases may be individually (or independently) introduced (or supplied) into of the valve block 131b (i.e., each of the internal gas passages). Each of the plurality of gases may be (independently) separated into different outlets through each of the internal gas passages and then discharged from the inside of the valve block 131b, but two or more of the internal gas passages may be mixed so that the two or more of the gases are discharged from the inside of the valve block 131b through the same outlet.

The two or more gases that are discharged from the inside of the valve block 131b through the same outlet may include a purge gas, a source purge gas SP may be discharged (or supplied) to purge the source gas S through the outlet through which the source gas S is supplied to the shower head part 120, and a reactant purge gas RP may be discharged to purge a reactant gas R through the outlet, through which the reactant gas R is supplied, to the shower head part 120.

Thus, the substrate processing apparatus 100 according to the present disclosure may reduce a footprint of the valve block 131b for supplying the plurality of gases to the shower head part 120 including the internal gas passage, and thus, an overall size of the equipment may be reduced. In addition, the flow control of the plurality of gases through the (plurality of) valves 131a may be facilitated.

Here, an inner surface of the internal gas passage may be surface treated. To suppress particle generation when the gas is introduced into the valve block 131b (i.e., the internal gas passage), surface roughness of the inner surface of the internal gas passage may be managed, and the surface roughness of the inner surface of the internal gas passage may be controlled (or adjusted) by surface-treating the inner surface of the internal gas passage.

If the inner surface of the internal gas passage is not smooth, but rather bumpy (or sharply pointed), when the flow of the gas is strong (or fast), the bumpy protruding portion of the inner surface of the internal gas passage may be worn away by the flow of the gas, resulting in contaminants such as particles. In addition, when the flow of the gas is weak (or slow), the gas remains between the bumpy portion of the inner surface of the internal gas passage to adhere to the inner surface of the internal gas passage in the form of particles and/or films (or thin films) and then may be injected onto the substrate 10 together with the gas supplied by the gas supply, thereby acting as impurities. However, in the substrate processing apparatus 100 according to the present disclosure, the inner surface of the internal gas passage may be surface-treated to be smooth so as to suppress and/or prevent the inner surface of the inner gas passage from being worn away by a rapid (or strong) flow of the gas and prevent and/or suppress the gas from remaining on the inner gas passage (for example, the inner surface of the inner gas passage).

Thus, the substrate processing apparatus 100 according to the present disclosure may maximize the purge effect of the gas line 132 and/or the internal gas passage by using the integral valve block 131b having the internal gas passage therein and may improve the contamination by the particles, etc. by operating so that a stable temperature is maintained by mounting the heater 131d on the valve block 131b.

In addition, the valve block part 131 may further include a plurality of gaskets 131c, each of which is provided between each of the plurality of valves 131a and the valve block 131b. The plurality of gaskets 131c may be provided between the plurality of valves 131a and the valve block 131b, respectively, and may maintain a gas seal between each of the valves 131a and the valve block 131b to prevent leakage of the gas between the valve 131a and the internal gas passage. For example, the plurality of gaskets 131c may include a metal gasket and have excellent pressure and heat resistance so that even if the gas flows at a high pressure, the seal is maintained between each valve 131a and the valve block 131b, and even if the valve block 131b is heated by the heater 131d, the seal is stably maintained between each valve 131a and the valve block 131b without deformation.

Here, the valve block part 131 may be directly connected to the inlet 121 of the shower head part 120. The valve block part 131 may be directly connected to the inlet 121 of the shower head part 120 to minimize a distance between the inlet 121 of the shower head part 120 and the valve 131a, and thus, the plurality of gases may be supplied sequentially while each gas is supplied instantaneously, and the atomic layer deposition (ALD) process may be stably performed without the time delay due to the long distance between the inlet 121 of the shower head part 120 and the valve 131a.

The plurality of gases may include a source gas S and a reactant gas R, and the source gas S and the reactant gas R may be separately introduced into the inlet 121 of the shower head part 120. The plurality of gases may include the source gas S and the reactant gas R that reacts with the source gas. The source gas S may include titanium tetrachloride (TiCl₄) and dichlorosilane (DCS, SiH₂Cl₂). In addition, the reactant gas R may react with the source gas, be different from the source gas, and include ammonia (NH₃) and hydrogen (H₂), etc.

Here, the atomic layer deposition (ALD) process may be performed by injecting (or supplying) the source gas S and the reactant gas R onto the substrate 10 while being temporally (and/or spatially) separated from each other. For this, the source gas S and the reactant gas R may be introduced into the inlet 121 of the shower head part 120 while being temporally and/or spatially separated from each other. For example, the inlet 121 of the shower head part 120 may be provided as an inlet port or may be provided in the form of a nozzle that is capable of injecting the gas inside the shower head part 120 (for example, the inner (wall) surface of the shower head part). To spatially separate and supply the source gas S and the reactant gas R, two outlet ports may be provided in the valve block 131b, and the inlets 121 may be provided with two inlet ports or nozzles in the shower head part 120 to communicate with the two outlet ports.

In addition, the plurality of gases may further include a source purge gas SP and a reactant purge gas RP. The source purge gas SP may purge the source gas, and the reactant purge gas RP may purge the reactant gas. Each of the source purge gas SP and the reactant purge gas RP may be an inert gas and may include, but are not particularly limited thereto, nitrogen (N₂), hydrogen (H₂), and argon (Ar). Here, the source purge gas SP and the reactant purge gas RP may be the same type or different types of gases, and at least their functions and supply (or injection) may be different from each other. The source purge gas SP and the reactant purge gas RP may be different in at least one of an injection amount, an injection pressure, or an injection rate depending on their functions, but all the injection amount, the injection pressure, and the injection rate may be the same.

The valve 131a may be configured as an on-off valve, but may also be configured as a split valve. When the valve 131a is configured as the split valve, the valve 131a may be provided in plurality or, but one valve 131a may be provided. Here, the split valve may selectively supply the plurality of gases depending on a rotation angle of a switching part (not shown). For example, when four gases are provided, and an angle of 360° is divided into four angles, a first gas (e.g., the source gas) may be supplied at an angle of about 0° (or an angle range of about 0° to about) 90°, a second gas (e.g., the source purge gas) may be supplied at an angle of about 90° (or an angle range of about 90° to about) 180°, a third gas (e.g., the reactant gas) may be supplied at an angle of about 180° (or an angle range of about 180° to about) 270°, and a fourth gas (e.g., the reactant purge gas) may be supplied at an angle of about 270° (or an angle range of about 270° to about) 360°.

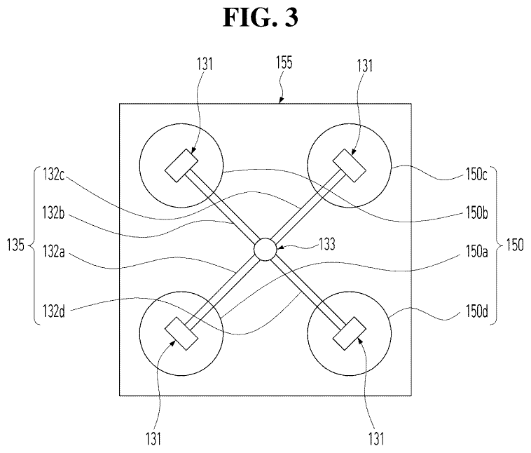

FIG. 3 is a conceptual view for explaining the gas supply part that supplies the process gas to a plurality of sub-chambers according to an exemplary embodiment.

Referring to FIG. 3, the substrate processing apparatus 100 according to the present disclosure may be provided with the substrate support 110 and the shower head part 120 and may further include a plurality of sub-chambers 150 in which processes are performed independently.

Each of the plurality of sub-chambers 150 may be provided with the substrate support 110 and the shower head part 120 to perform a process for the substrate 10. In the plurality of sub-chambers 150, the processes may be independently performed, and the processes for the plurality of substrates 10 may be performed in each of the plurality of sub-chambers 150. Here, the plurality of sub-chambers 150 may be spatially separated (or isolated) by a partition wall or the like to form a chamber module or may be regionally divided into the plurality of sub-chambers 150 in which the processes are independently performed (for example, into a first sub-chamber, a second sub-chamber, a third sub-chamber, and a fourth sub-chamber) within the chamber wall 155 to form a chamber module. For example, the first sub-chamber 150a, the second sub-chamber 150b, the third sub-chamber 150c, and the fourth sub-chamber 150d, which are provided within the chamber wall 155 of the chamber module, may be only regionally separated from each other within the chamber wall 155, but may communicate with each other so as not to be spatially separated by the partition wall or the like.

Each of the first sub-chamber 150a, the second sub-chamber 150b, the third sub-chamber 150c, and the fourth sub-chamber 150d may independently perform the process and be provided as the same configuration such as the substrate support 110 and the shower head part 120, and numbers of the sub-chambers 150 may be distinguished from each other by location (or area).

For example, the first sub-chamber 150a may include a first substrate support 110 on which a first substrate 10 is supported, and a first shower head part 120 provided on the first substrate support 110 to inject a gas for the substrate processing onto the first substrate 10 supported by the first substrate support 110, and the second sub-chamber 150b may include a second substrate support 110 on which a second substrate 10 is supported, and a second shower head part 120 provided on the second substrate support 110 to inject a gas for the substrate processing onto the second substrate 10 supported by the second substrate support 110.

The first shower head part 120 and the second shower head part 120 may be connected to the gas line 132 and may be provided to the first sub-chamber 150a and the second sub-chamber 150b, respectively. Any one gas of the plurality of gases may be selectively supplied to the first shower head part 120 and the second shower head part 120 so that the supplied gas is injected. Here, the same gas or different gases may be supplied to the first shower head part 120 and the second shower head part 120.

In addition, the first substrate support 110 and the second substrate support 110 may be provided in the first sub-chamber 150a and the second sub-chamber 150b to support the first substrate 10 and the second substrate 10, respectively. Thus, the plurality of substrates 10 may be processed simultaneously in one chamber module to improve process yield.

Here, the gas supply part 130 may further include a gas hub 133 to which the process gas is supplied, and a branch line part 135 constituted by the gas lines 132 branched from the gas hub 133 and connected respectively to the shower head part 120 of each of the plurality of sub-chambers 150. The gas hub 133 may be configured to supply the process gas from the gas supply source (not shown), and a gas supply line (not shown) may be connected to the gas hub 133 so that the process gas is supplied from the gas supply source (not shown) through the gas supply line (not shown). Here, the gas hub 133 may be first (or primarily) filled with the process gas, and after the process gas is filled inside tightly (or completely) so that an internal pressure becomes uniform overall, the gas may be branched into a branch line part 135 constituted by gas lines 132a, 132b, 132c, and 132d and then supplied to the plurality of gas lines 132. For example, the gas hub 133 may have sub spaces having the same number as the branch gas lines 132a, 132b, 132c, and 132d of the branch line part 135, and each of the sub spaces may communicate with each other, and thus, the process gas supplied from one gas supply line (not shown) may be completely filled and be partially blocked by the partition wall or the like so that an area is divided (or segmented). Here, the process gas may be first filled into each of the sub spaces and supplied to each of the gas lines 132a, 132b, 132c, and 132d in a state in which (or after) the pressures of all the sub spaces become the same (or uniform).

The branch line part 135 may be constituted by gas lines 132a, 132b, 132c, and 132d branched from the gas hub 133 and connected to the shower head part 120 of each of the plurality of sub-chambers 150, and the process gas branched from the gas hub 133 may be supplied to flow, and the supplied process gas may be transferred to each sub-chamber 150 and/or the shower head part 120. For example, each of the gas lines 132a, 132b, 132c, and 132d of the branch line part 135 branched from the gas hub 133 may be connected to a different sub-chamber 150 and/or shower head part 120, and the processing process for each substrate 10 may be performed in each sub-chamber 150. Here, the process may be performed independently in each sub-chamber 150, and the same process may be performed, or different processes may be performed in each sub-chamber 150.

Here, the gas hub 133 may be provided in plurality so that the plurality of gases are supplied respectively, and the branch line part 135 may be provided in each of the gas hubs 133. The gas hub 133 may be provided in plurality and may be stacked in a vertical direction (or a direction perpendicular to a radial direction of the gas hub), and each of the plurality of gases may be supplied to each of the plurality of gas hubs 133, and the plurality of gases may be filled (independently or individually) into the plurality of gas hubs 133, respectively. Here, each gas hub 133 may be filled with the same gas or may be filled with different gases, and depending on the number of plurality of gases, some groups of the gas hubs 133 may be filled with the same gas, and each of the remaining gas hubs 133 may be filled with a different gas that is not the same (or different) from the gas filled in the gas hubs 133 of the some groups. In addition, the plurality of gas hubs 133 may be stacked in the vertical direction (for example, in an upward and downward direction), and at least two gas lines 132a, 132b, 132c, and 132d may be branched and connected to each gas hub 133, and the gas lines 132a, 132b, 132c, and 132d of the branch line part 135 connected (or branched) to each gas hub 133 may extend radially from each gas hub 133. Thus, there may be no interference between the plurality of gas lines 132, and the plurality of gases may be stably supplied to each shower head part 120. In addition, when the plurality of gas hubs 133 are stacked in the vertical direction, the gas lines 132a, 132b, 132c, and 132d of the branch line part 135 may be branched horizontally from each gas hub 133 to extend so that the gas flows (or is supplied) evenly to each of the gas lines 132a, 132b, 132c, and 132d of the branch line part 135 branched from each gas hub 133.

That is, the branch line part 135 may be provided to each gas hub 133, and the gas lines 132a, 132b, 132c, and 132d of the branch line part 135 branched from each gas hub 133 may stably supply the plurality of gases to each shower head part 120 without interference.

In addition, the plurality of valves 131a may be connected respectively to the gas lines 132 that are connected to the shower head part 120 of the same (or identical) sub-chamber 150 by extending in the same direction from the different gas hubs 133, and each of the gas lines 132 connected to the shower head part 120 of the same sub-chamber 150 may be included in each of the branch line parts 135 (one by one) and be provided in each branch line part 135. The plurality of valves 131a may be connected to the gas lines 132 for each of the gases supplied from different gas hubs 133, and each of the gas lines 132 for the gases may be one gas line 132 from each of the plurality of branch line parts 135 (or for each of the branch line parts) and may extend in the same direction from the different gas hubs 133 and be connected to the shower head part 120 of the same (or identical) sub-chamber 150. As a result, the plurality of gases may be supplied to each sub-chamber 150, and the plurality of valves 131a may be controlled to selectively (e.g., sequentially) supply the plurality of gases. The atomic layer deposition (ALD) process may be performed by sequentially supplying the plurality of gases.

The gas hub 133 and the plurality of gas lines 132 may be simultaneously heated by an integrated heater (not shown). The integrated heater (not shown) may include a thermally conductive block surrounding the plurality of gas lines 132 and the gas hub 133 and a heating element that at least partially contacts the thermally conductive block to heat the thermally conductive block. The thermally conductive block may surround the plurality of gas lines 132 and the gas hub 133 and may be heated by the heating element to transfer heat to the plurality of gas lines 132 and the gas hub 133, thereby allowing the process gas within the gas hub 133 and the plurality of gas lines 132 to be heated. For example, the thermally conductive block may surround the plurality of gas lines 132 and the gas hub 133 at the same time, and the gas hub 133 and the plurality of gas lines 132 may be heated simultaneously by thermal conduction.

The heating element may at least partially contact the thermally conductive block to heat the thermally conductive block and may transfer heat to the plurality of gas lines 132 and the gas hub 133 through the thermally conductive block so as to be heated. Here, the heating element may be in close contact with the thermally conductive block so that the heat is well conducted (or transferred) to the thermally conductive block. The heating element may be attached to and detached from the thermally conductive block and may be replaced by being coupled to and separated from the thermally conductive block.

Here, the thermally conductive block may include a hub accommodation part that surrounds the gas hub 133 and a gas line accommodation part that surrounds the plurality of gas lines 132. The hub accommodation part may surround the gas hub 133, cover an entire outer surface of the gas hub 133, and contact (or adhere to) an outer surface of the gas hub 133 to transfer (or conduct) the heat of the heating element to the gas hub 133, thereby allowing the gas hub 133 to be heated for heating the process gas.

The gas line accommodation part may be (integrally) coupled (or connected) to the hub accommodation part and may surround the plurality of gas lines 132, and each gas line 132 may extend from the hub accommodation part in a direction in which each gas line 132 is branched from the gas hub 133. For example, the gas line accommodation part may extend outwardly (in the direction) from the outer surface (or peripheral surface) of the hub accommodation part by surrounding (or enclosing) a circumference of the hub accommodation part, thereby surrounding the plurality of gas lines 132 at once or may be extend in the branched direction of the gas lines 132 by contacting the outer surface of the hub accommodation part, thereby surrounding each (other) of the gas lines 132 in each (branched) direction (or in the same direction). Here, the gas line accommodation part may surround the gas lines 132 in each of the branch line parts 135 connected to the shower head part 120 of the same sub-chamber 150 (or the gas lines for each gas at once). As a result, the gas line accommodation part may conduct (or transfer) the heat of the heating element to all of the gas lines 132 by being in close contact with (or in contact with) the outer surface of each of the plurality of gas lines 132, thereby heating the plurality of gas lines 132 and heating the process gas within the plurality of gas lines 132. The gas line accommodation part may be constituted by two blocks, and each block may have a groove defined to be fitted into the shape of the gas line 132 so as to be capable of surrounding the gas line 132.

In addition, the valve block part 131 may be configured as an integrated type. For example, the valve block part 131 may be an integrated gas supply system (IGS) and may be a modularized and/or miniaturized system that controls supply of fluid (e.g., supply of the process gas) by connecting and integrating pipes (e.g., the gas line) used in semiconductor pre-process equipment (CVD, etching, metal, etc.) with the block and the metal gasket (e.g., the valve block and the plurality of gaskets), and the plurality of valves 131a may be valves of the integrated gas supply system (IGS) type. As a result, a space (dead volume) that is not used for the gas supply (e.g., supply of the process gas) within the valve block 131b may be reduced to reduce the overall equipment size.

In addition, the gas supply part 130 may selectively supply the plurality of gases to the first sub-chamber 150a, the second sub-chamber 150b, the third sub-chamber 150c, and the fourth sub-chamber 150d and may separately supply the plurality of gases to the first sub-chamber 150a, the second sub-chamber 150b, the third sub-chamber 150c, and the fourth sub-chamber 150d, respectively. The gas supply part 130 may generally supply the same gas to all of the first sub-chamber 150a, the second sub-chamber 150b, the third sub-chamber 150c, and the fourth sub-chamber 150d, but may also supply different gases to the first sub-chamber 150a, the second sub-chamber 150b, the third sub-chamber 150c, and the fourth sub-chamber 150d by distinguishing the plurality of gases and also may supply a gas different from a gas supplied from the other sub-chambers 150S to at least one sub-chamber 150 of the first sub-chamber 150a, the second sub-chamber 150b, the third sub-chamber 150c, and the fourth sub-chamber 150d. Here, the number of gas supply sources (not shown) of the gas supply part 130 may be the same as the number of the plurality of gases may be the same as the number of sub-chambers 150, and the number of sub-chambers 150, and the number of the plurality of gases may be the same.

Here, the controller (not shown) may control the gas supply part 130 so that the plurality of gases are sequentially (or successively) supplied to the first to fourth sub-chambers 150a, 150b, 150c, and 150d by alternating the gases supplied between the first sub-chamber 150a, the second sub-chamber 150b, the third sub-chamber 150c, and also, the fourth sub-chamber 150d, and the respective supplied gases may be alternately supplied to the first sub-chamber 150a, the second sub-chamber 150b, the third sub-chamber 150c, and the fourth sub-chamber 150d, and the plurality of gases may be sequentially supplied differently from the gases supplied (or previously) immediately before.

For example, the plurality of gases may be supplied to each of the first sub-chamber 150a, the second sub-chamber 150b, the third sub-chamber 150c, and the fourth sub-chamber 150d in a predetermined order, and the gas to be supplied (next or subsequent) may be determined based on the gas supplied immediately before, and the gas may be supplied without overlapping (or duplicating) with the gas supplied immediately before.

Here, the plurality of gases may be circulated in order of the source gas S→the source purge gas SP→the reactant gas R→the reactant purge gas RP, and also, the source gas S may be supplied after the reactant purge gas RP, and the (supply) start gas may be different for each sub-chamber 150 so that different gases are supplied at the same time.

That is, the first sub-chamber 150a, the second sub-chamber 150b, the third sub-chamber 150c, and the fourth sub-chamber 150d may perform different processes by supplying different gases at the same time (or time) through the controller (not shown). Here, the different gases may include those (or cases) that are of the same type but have different functions.

For example, the first sub-chamber 150a may perform a process of depositing a source material layer (or atomic layer) by supplying the source gas S (first), the second sub-chamber 150b may perform a process of purging (the reactant gas) by supplying the reactant purge gas RP (first), the third sub-chamber 150c may perform a process of depositing a reaction material layer (or atomic layer) by supplying the reactant gas R (first), and the fourth sub-chamber 150d may perform a process of purging (the source gas) by supplying the source purge gas SP (first). The substrate processing apparatus 100 of the present disclosure may perform not only chemical vapor deposition (CVD) but also atomic layer deposition (ALD) and may deposit the source gas and the reactant gas in atomic layer units.

That is, the gases may be supplied to the first sub-chamber 150a in order of the source gas S→the source purge gas SP→the reactant gas R→the reactant purge gas RP, the gases may be supplied to the second sub-chamber 150b in order of the reactant purge gas RP→the source gas S→the source purge gas SP→the reactant gas R, the gases may be supplied to the third sub-chamber 150c in order of the reactant gas R→the reactant purge gas RP→the source gas S→the source purge gas SP, and the gases may be supplied to the fourth sub-chamber 150d in order of the source purge gas SP→the reactant gas R→the reactant purge gas RP→the source gas S.

Thus, the substrate processing apparatus 100 of the present disclosure may supply the plurality of gases (i.e., the source gas, the reactant gas, the source purge gas, and the reactant purge gas) separately to the first sub-chamber 150a, the second sub-chamber 150b, the third sub-chamber 150c, and the fourth sub-chamber 150d so that a constant amount of gas(es) is always supplied within the plurality of sub-chambers 150, and thus, the pressure within the plurality of sub-chambers 150 may be controlled to a stable process pressure, and the process pressure within the plurality of sub-chambers 150 may be maintained constantly (or the same). As a result, it is also possible to improve contamination of the plurality of sub-chambers 150 due to rapid changes in process pressure within the plurality of sub-chambers 150 according to the change in the gas.

Here, the plurality of valve block parts 131 may be installed close to (or adjacent to) each of the shower head parts 120 of the sub-chamber 150a, the second sub-chamber 150b, the third sub-chamber 150c, and the fourth sub-chamber 150d, and the plurality of valves 131a supported by each valve block 131b may be (directly) connected to (or communicate with) (each) shower head part 120. Thus, each of the plurality of valve block parts 131 may be controlled through the controller (not shown), and thus, each gas may be injected (or supplied) or stopped (or blocked) immediately (or right away). That is, depending on the opening and closing of the plurality of valves 131a, the source gas S may be immediately injected or stopped from being injected through the (respective) showerhead, the reactant gas R may be immediately injected or stopped from being injected through the (respective) showerhead, the source purge gas SP may be immediately injected or stopped from being injected through the (respective) showerhead, and the reactant purge gas RP may be immediately injected or stopped from being injected through the (respective) showerhead.

As a result, it is possible to suppress or prevent the supply of the process gas from being (briefly) cut off (or delayed) due to the opening and closing of the plurality of valves 131a according to the change in the gas. In the related art, even when a distance between the (each) shower head part 120 and each valve is long, and thus, the valve is opened, a time may be required for the gas to be supplied (or move) from the valve to the (each) shower head part 120, and the gas may not be immediately injected from the (each) shower head part 120. In addition, even when the valve is closed, there is a limitation in that the gas still remains between the valve and the (each) shower head part 120, and the gas is not immediately blocked but continues to be injected until all of the remaining gas is injected. However, in the present disclosure, the plurality of valves 131a may be installed (as close as possible) to the (each) shower head part 120 through the valve block part 131 so that the source gas S, the reactant gas R, the source purge gas SP and the reactant purge gas RP are immediately injected or stopped from being injected through the (each) shower head part 120 according to the opening and closing of the plurality of valves 131a.

As described above, in the present disclosure, the valve block part may be installed on the upper portion of the shower head part so that the position of the valve that controls the supply of the process gas is as close as possible to the inlet of the shower head part to shorten the supply time of the process gas, thereby enabling the stable gas supply and improving the productivity. That is, since the valve has the minimum distance from the inlet of the shower head part, there may be no limitation in supplying the process gas instantaneously, and since the gas supply of about 0.2 ms or less is possible, the atomic layer deposition (ALD) process may be performed stably without the time delay due to the length of the gas line. In addition, the valve block may include the internal gas passage to reduce the footprint for supplying the plurality of gases to the shower head part, thereby reducing the overall size of the equipment, and easily controlling the flow of the plurality of gases through the valve. In addition, the integrated valve block having the internal gas passage may be used to maximize the purge effect of the gas line, and the heater may be mounted on the valve block to stably maintain the temperature, thereby improving the contamination due to the particles.

In the substrate processing apparatus according to the embodiment of the present disclosure, the valve block part may be installed on the upper portion of the shower head part so that the position of the valve that controls the supply of the process gas is as close as possible to the inlet of the shower head part to shorten the supply time of the process gas, thereby enabling the stable gas supply and improving the productivity.

That is, since the valve has the minimum distance from the inlet of the shower head part, there may be no limitation in supplying the process gas instantaneously, and since the gas supply of about 0.2 ms or less is possible, the atomic layer deposition (ALD) process may be performed stably without the time delay due to the length of the gas line.

In addition, the valve block may include the internal gas passage to reduce the footprint for supplying the plurality of gases to the shower head part, thereby reducing the overall size of the equipment, and easily controlling the flow of the plurality of gases through the valve.

In addition, the integrated valve block having the internal gas passage may be used to maximize the purge effect of the gas line, and the heater may be mounted on the valve block to stably maintain the temperature, thereby improving the contamination due to the particles.

Although embodiments have been described with reference to a number of illustrative embodiments thereof, the embodiments are not limited to the foregoing embodiments, and thus, it should be understood that numerous other modifications and embodiments may be devised by those skilled in the art that will fall within the spirit and scope of the principles of this disclosure. Hence, the real protective scope of the present disclosure shall be determined by the technical scope of the accompanying claims.

1. A substrate processing apparatus comprising:
a substrate support on which a substrate is supported;
a shower head part provided to face the substrate support and configured to inject a process gas toward the substrate; and
a gas supply part configured to supply the process gas to the shower head part,
wherein the gas supply part comprises a valve block part installed on an upper portion of the shower head part to adjust a flow of the process gas.

2. The substrate processing apparatus of claim 1, wherein the process gas comprises a plurality of gases, and
the gas supply part is configured to sequentially supply the plurality of gases to the shower head part.

3. The substrate processing apparatus of claim 2, wherein the valve block part comprises:
a plurality of valves to which a plurality of gas lines, through which the plurality of gases are supplied, are connected, respectively; and
a valve block fixed to a top surface of the shower head part to support the plurality of valves.

4. The substrate processing apparatus of claim 3, wherein the valve block part further comprises a heater configured to heat the valve block.

5. The substrate processing apparatus of claim 4, wherein the valve block part further comprises a temperature measuring member configured to measure a temperature of the valve block.

6. The substrate processing apparatus of claim 3, wherein the valve block comprises an internal gas passage connected to each of the plurality of gas lines, and
the valve is configured to control a flow of each of the plurality of gases in the internal gas passage.

7. The substrate processing apparatus of claim 6, wherein an inner surface of the internal gas passage is surface-treated.

8. The substrate processing apparatus of claim 6, wherein the valve block part further comprises a plurality of gaskets, each of which is provided between each of the plurality of valves and the valve block.

9. The substrate processing apparatus of claim 2, wherein the valve block part is directly connected to an inlet of the shower head part.

10. The substrate processing apparatus of claim 9, wherein the plurality of gases comprise a source gas and a reactant gas, and
the source gas and the reactant gas are separated to be introduced into the inlet of the shower head part.

11. The substrate processing apparatus of claim 3, further comprising a plurality of sub-chambers, each of which is provided with the substrate support and the shower head part and in which processes are performed independently, and
the gas supply part comprises:
a gas hub to which the process gas is supplied; and
a branch line part constituted by the gas lines branched from the gas hub and connected respectively to the shower head part of each of the plurality of sub-chambers.

12. The substrate processing apparatus of claim 1140, wherein the gas hub is provided in plurality and each of the plurality of gases is supplied to each of the gas hubs, and
the branch line part is provided in each of the gas hubs.

13. The substrate processing apparatus of claim 12, wherein the plurality of valves are connected respectively to the gas lines that are connected to the shower head part of the same sub-chamber by extending in the same direction from the different gas hubs.

14. The substrate processing apparatus of claim 1, wherein the valve block part is configured as an integrated type.
